(19) United States
(12) Patent Application Publication
(10) Pub. No.: US 2021/0376294 A1
(43) Pub. Date: Dec. 2, 2021

(54) ORGANIC LIGHT EMITTING DIODE DISPLAY PANEL AND MANUFACTURING METHOD THEREOF

(71) Applicant: Wuhan China Star Optoelectronics Semiconductor Display Technology Co., Ltd., Wuhan (CN)

(72) Inventor: Peng WANG, Wuhan (CN)

(73) Assignee: Wuhan China Star Optoelectronics Semiconductor Display Technology Co., Ltd., Wuhan (CN)

(21) Appl. No.: 16/637,755

(22) PCT Filed: Nov. 6, 2019
(86) PCT No.: PCT/CN2019/115933

§ 371 Date: Feb. 9, 2020

(30) Foreign Application Priority Data
Sep. 3, 2019 (CN) 201910825715.3

(51) Int. Cl. H01L 51/52; H01L 51/56; H01L 27/32

(52) U.S. Cl. CPC H01L 51/5259; H01L 2227/323; H01L 27/3244; H01L 51/56

(57) ABSTRACT

Provided are an OLED display panel and a manufacturing method thereof. The OLED display panel includes an array substrate, pixel electrodes disposed on the array substrate, a retaining wall disposed on the array substrate and a luminescent material layer disposed on the pixel electrodes; wherein the retaining wall includes openings corresponding to the pixel electrodes in one-to-one correspondence, and the retaining wall includes a plurality of first split bodies and a plurality of second split bodies which are criss-crossed, and a groove is disposed on one side of the first split body and on one side of the second split body away from the array substrate.

### FIELD OF THE INVENTION

The present invention relates to a display field, and more particularly to an organic light emitting diode display panel and a manufacturing method thereof.

### BACKGROUND OF THE INVENTION

For an organic electroluminescence (OLED) device, a pixel pattern is generally defined on a planar substrate using a dam, and then materials of respective layers of the display device are formed into a film within the range in which the dam is formed.

Inkjet printing is an efficient and low cost method of forming a luminescent layer. As shown in FIG. 1, the dam 11 generally has a certain height, and when the luminescent layer 12 is formed by inkjet printing, ink droplets dropped from the nozzles are confined between adjacent dams 11, thereby forming the luminescent layer 12.

However, due to process factors, such as alignment accuracy or fluctuations in inkjet amount, ink droplets may be biased toward one side of the dam 11. Once a small amount of ink droplets passed over the dam 11, the ink droplets that passed over the dam 11 may easily enter adjacent pixels, causing different ink droplet materials to mix, thereby affecting the display effect.

Thus, as inkjet printing is used to form the luminescent layer, once a small amount of ink droplets passed over the dam, the ink droplets that passed over the dam may easily enter adjacent pixels, causing different ink droplet materials to mix, thereby affecting the display effect.

### SUMMARY OF THE INVENTION

Provided is an OLED display panel, including:

an array substrate;

a plurality of pixel electrodes disposed at intervals on the array substrate;

a retaining wall disposed on the array substrate; and

a luminescent material layer and a cathode layer laminated on the pixel electrode;

wherein the retaining wall includes openings corresponding to the pixel electrodes in one-to-one correspondence, and the retaining wall includes a plurality of first split bodies and a plurality of second split bodies which are criss-crossed, and a groove is disposed on one side of the first split body and on one side of the second split body away from the array substrate; a longitudinal section of the groove is an inverted trapezoid; a hydrophilic layer having hydrophilicity is disposed on side walls and a bottom of the groove.

Furthermore, the groove on the first split body along a length direction of the first split body, and the groove on the second split body along a length direction of the second split body.

Furthermore, the grooves on all of the first split bodies and the grooves on all of the second split bodies are communicated to each other.

Furthermore, the grooves are disposed at junctions of the first split bodies and the second split bodies.

Furthermore, the grooves are disposed at all of the junctions of the first split bodies and the second split bodies.

Furthermore, a sinker is disposed at a position corresponding to the groove on the array substrate, and an orthographic projection of the sinker on the array substrate encloses an orthographic projection of the groove on the array substrate.

Furthermore, a cross section of the opening is elliptical or rounded rectangular.

Provided is an OLED display panel, including:

an array substrate;

a plurality of pixel electrodes disposed at intervals on the array substrate;

a retaining wall disposed on the array substrate; and

a luminescent material layer and a cathode layer laminated on the pixel electrode;

wherein the retaining wall includes openings corresponding to the pixel electrodes in one-to-one correspondence, and the retaining wall includes a plurality of first split bodies and a plurality of second split bodies which are criss-crossed, and a groove is disposed on one side of the first split body and on one side of the second split body away from the array substrate.

Furthermore, the groove on the first split body along a length direction of the first split body, and the groove on the second split body along a length direction of the second split body.

Furthermore, the grooves on all of the first split bodies and the grooves on all of the second split bodies are communicated to each other.

Furthermore, the grooves are disposed at junctions of the first split bodies and the second split bodies.

Furthermore, the grooves are disposed at all of the junctions of the first split bodies and the second split bodies.

Furthermore, a sinker is disposed at a position corresponding to the groove on the array substrate, and an orthographic projection of the sinker on the array substrate encloses an orthographic projection of the groove on the array substrate.

Furthermore, a longitudinal section of the groove is an inverted trapezoid.

Furthermore, a hydrophilic layer having hydrophilicity is disposed on side walls and a bottom of the groove.

Furthermore, a cross section of the opening is elliptical or rounded rectangular.

The present invention further provides a manufacturing method of an OLED display panel, including steps of:

Step S10, providing an array substrate;

Step S20, forming a plurality of pixel electrodes arranged at intervals on the array substrate;

Step S30, forming a retaining wall covering the pixel electrodes on the array substrate;

Step S40, forming openings corresponding to the pixel electrodes in one-to-one correspondence in the retaining wall, and forming a groove on one side of a first split body and on one side of a second split body away from the array substrate; and

Step S50, laminating a luminescent material layer and a cathode layer on the pixel electrode.

By providing grooves on the first split bodies and second split bodies, as the luminescent material layer is formed in the openings by inkjet printing, the small amount of ink droplets spilling over the retaining wall can smoothly enter the grooves for storage and then, the ink droplets evaporate during subsequent evaporation process of solvent. Thus, the ink droplets are prevented from crossing the retaining wall and entering adjacent pixel openings to result in mixing of different ink drop materials and to reduce the risk of color mixing as forming the luminescent material layer by using ink jet printing.

### BRIEF DESCRIPTION OF THE DRAWINGS

In order to more clearly illustrate the embodiments of the present invention and the prior art, the following figures will be described in the embodiments and the prior art are briefly introduced. It is obvious that the drawings are only some embodiments of the present invention, those of ordinary skill in this field can obtain other figures according to these figures without paying the premise.

FIG. 1 is a structural diagram of an organic electroluminescent device in the prior art of the present invention;

FIG. 2 is a structural diagram of an organic light emitting diode (OLED) display panel according to an embodiment of the present invention;

FIG. 3 is a plan view diagram of a groove and a retaining wall according to embodiment one of the present invention;

FIG. 4 is a cross section diagram of a first split body or a second split body in one specific embodiment of the present invention;

FIG. 5 is a structural diagram of a luminescent material layer according to one embodiment of the present invention;

FIG. 6 is a plan view diagram of a groove and a retaining wall according to embodiment two of the present invention;

FIG. 7 is a structural diagram of an array substrate and a retaining wall in one embodiment of the present invention; and

FIG. 8 is a manufacturing flowchart of an OLED display panel according to the present invention.

### REFERENCE NUMERALS

11 dam; 12 luminescent layer;
20 array substrate; 21 substrate; 22 thin film transistor array layer; 23 planarization layer; 231 sinker; 30 pixel electrode; 40 retaining wall; 41 first split body; 42 second split body; 50 opening; 60 groove; 70 luminescent material layer; 71 hole injection layer; 72 hole transport layer; 73 luminescent layer; 74 electron injection layer; 75 electron transport layer; 80 cathode layer; 90 hydrophilic layer.

### DETAILED DESCRIPTION OF PREFERRED EMBODIMENTS

The following descriptions for the respective embodiments are specific embodiments capable of being implemented for illustrations of the present invention with referring to appended figures. The terms of up, down, front, rear, left, right, interior, exterior, side, etcetera are merely directions of referring to appended figures. Thus, the used directional terms are used to describe and understand the present invention, but the present invention is not limited thereto. In the figure, units with similar structures are denoted by the same reference numerals.

The present invention is directed to the technical issue of the OLED display panel of the prior art that once a small amount of ink droplets passed over the dam, the ink droplets that passed over the dam may easily enter adjacent pixels, causing different ink droplet materials to mix, thereby affecting the display effect. The present invention can solve the aforesaid problems.

### Embodiment One

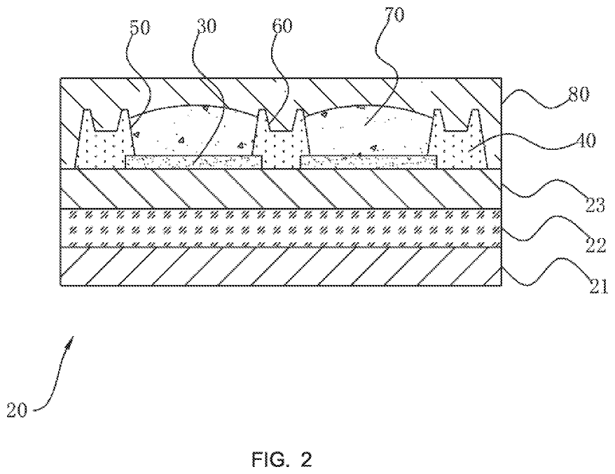

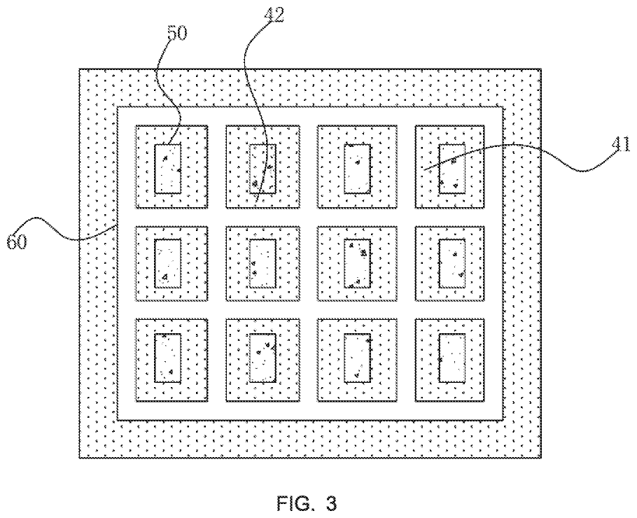

Provided is an OLED display panel. As shown in FIG. 2 and FIG. 3, the OLED display panel includes an array substrate 20, a plurality of pixel electrodes 30 disposed at intervals on the array substrate 20, a retaining wall 40 disposed on the array substrate 20, and a luminescent material layer 70 and a cathode layer 80 laminated on the pixel electrode 30.

Specifically, the array substrate 20 includes a substrate 21, a thin film transistor array layer 22 disposed on the substrate 21 and a planarization layer 23 disposed on the thin film transistor array layer 22. The pixel electrode 30 and the retaining wall 40 are disposed on the planarization layer.

The substrate 21 may be a flexible substrate 21 or a rigid substrate 21.

In one embodiment, the OLED display panel is a top-emitting OLED display panel. The pixel electrode 30 is formed of a material having high reflectivity, such as a silver material.

In another embodiment, the OLED display panel is a bottom-emitting OLED display panel. The pixel electrode 30 is formed of a material having high transmittance, such as a transparent conductive metal.

Specifically, the pixel electrodes 30 are arranged in an array. The retaining wall 40 includes openings 50 corresponding to the pixel electrodes 30 in one-to-one correspondence, and the retaining wall 40 includes a plurality of first split bodies 41 and a plurality of second split bodies 42 which are criss-crossed, and a groove 60 is disposed on one side of the first split body 41 and on one side of the second split body 42 away from the array substrate 20.

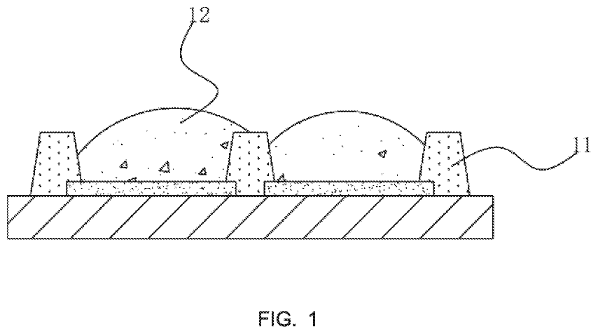

Specifically, as referring to FIG. 1, the one side of the first split body 41 and the one side of the second split body 42 away from the array substrate 20 are the top side of the retaining wall 40.

By providing grooves 60 on the first split bodies 41 and second split bodies 42, as the luminescent material layer 70 is formed in the openings 50 by inkjet printing, the small amount of ink droplets spilling over the retaining wall 40 can smoothly enter the grooves 60 for storage and then, the ink droplets evaporate during subsequent evaporation process of solvent. Thus, the ink droplets are prevented from crossing the retaining wall 40 and entering adjacent pixel openings 50 to result in mixing of different ink drop materials and to reduce the risk of color mixing as forming the luminescent material layer 70 by using ink jet printing.

Specifically, a shape of a cross section of the groove 60 is strip-shaped as a whole. The groove 60 on the first split body 41 along a length direction of the first split body, and the groove 60 on the second split body 42 along a length direction of the second split body.

Furthermore, the grooves 60 on all of the first split bodies 41 and the grooves 60 on all of the second split bodies 42 are communicated to each other.

Further, a groove 60 is disposed between the adjacent openings 50.

All of the openings 50 are surrounded by the grooves 60 to better prevent ink droplets from crossing the retaining wall 40 and entering adjacent pixel openings 50 to result in mixing of different ink drop materials. Meanwhile, all of the grooves 60 are communicated to each other to increase the amount of liquid stored in the grooves 60, and to prevent the ink droplets stored in the grooves 60 from spilling over the grooves 60.

Specifically, FIG. 3 merely illustrates the case where the shape of the cross section of the opening 50 is rectangular as a whole. In a practical implementation, the shape of the cross section of the opening 50 may also be elliptical or rounded rectangular.

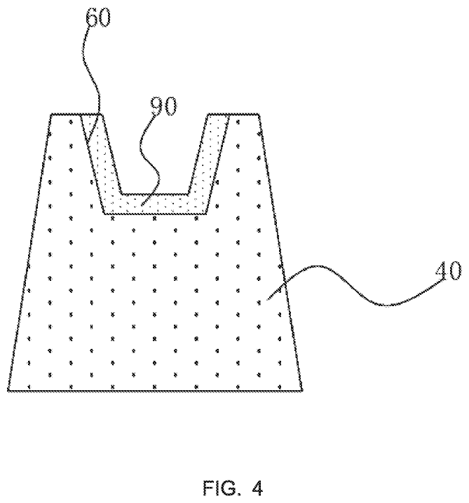

As shown in FIG. 4, in one embodiment, the retaining wall 40 is formed of a hydrophobic material. A hydrophilic layer 90 having hydrophilicity is disposed on side walls and a bottom of the groove 60.

In one embodiment, the cross section of the first split body 41 and the cross section of the second split body 42 both are trapezoids, and the longitudinal section of the opening 50 is an inverted trapezoid.

The retaining wall 40 is formed of a hydrophobic material, and the retaining wall 40 is disposed in an appropriate shape, so that the ink droplets can be better confined in the opening 50. The hydrophilic hydrophilic layer 90 is disposed on the side walls and the bottom of the groove 60, and the groove 60 is configured in a proper shape so that the ink droplets spilling over the retaining wall 40 can be better attracted and stored.

Specifically, in actual implementation, the longitudinal cross section of the opening 50 may be set to be other shapes, such as trapezoidal, rectangular, semicircular or elliptical, which are not enumerated here.

In one embodiment, a width of the groove 60 is one third of a width of the top of the first split body 41 or/and the second split body 42.

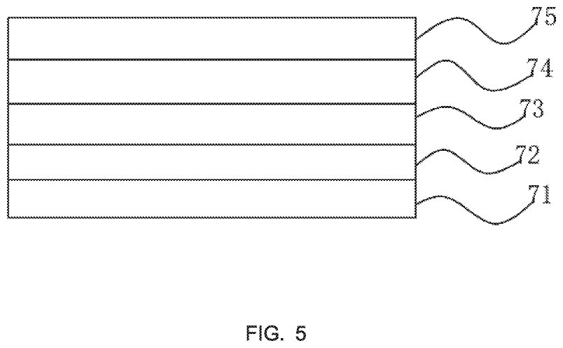

In one embodiment, as shown in FIG. 5, the luminescent material layer 70 includes a hole injection layer 71, a hole transport layer 72, a luminescent layer 73, an electron injection layer 74 and an electron transport layer 75, which are sequentially stacked.

### Embodiment Two

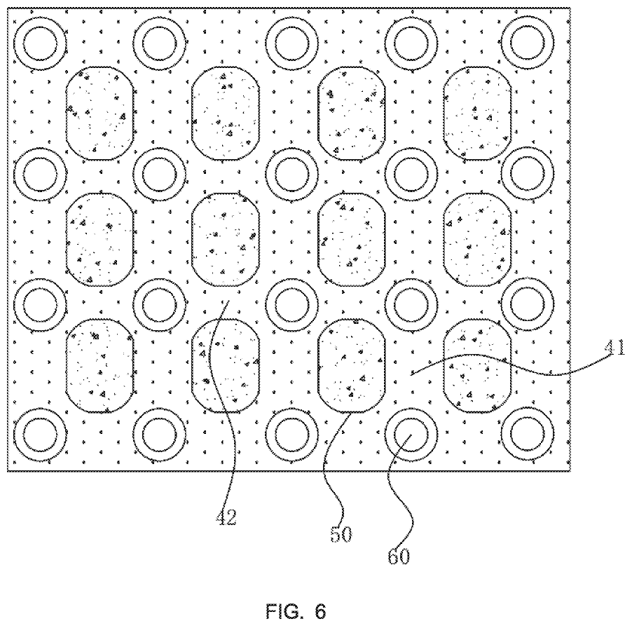

Provided is an OLED display panel. As shown in FIG. 6, it differs from embodiment one in that the shape and arrangement position of the grooves 60 are different.

Specifically, the grooves 60 are disposed at the junctions of the first split bodies 41 and the second split bodies 42. Therefore, it is not necessary to widen the width of the tops of the first split body 41 and the second split body 42 due to disposing the grooves 60, and the area of the opening 50 is increased to improve the display effect.

Specifically, the junction of the first split body 41 and the second split body 42 is an intersection of the first split body 41 and the second split body 42.

Furthermore, the grooves 60 are disposed at all of the junctions of the first split bodies 41 and the second split bodies 42.

Specifically, a shape of the cross section of the groove 60 is circular.

Specifically, the shape of the cross section of the groove 60 may also be elliptical, polygonal or semicircular, which are not enumerated here.

Furthermore, a cross section of the opening 50 is elliptical or rounded rectangular.

A circular arc transition is provided at the corners of the retaining wall 40 to form a more uniform film of the device within the opening 50 defined by the retaining wall 40.

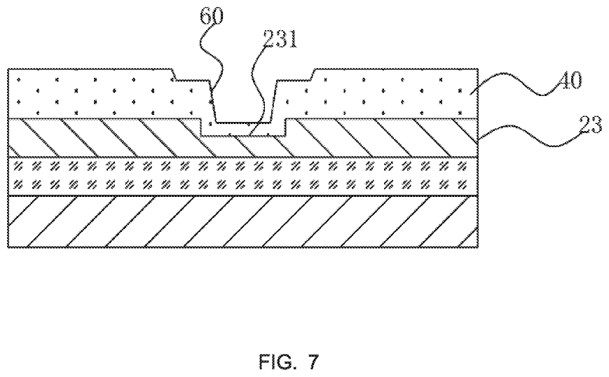

As shown in FIG. 7, a sinker 231 is disposed at a position corresponding to the groove 60 on the array substrate 20, and the sinker 231 is disposed on the planarization layer, and an orthographic projection of the sinker 231 on the array substrate 20 encloses an orthographic projection of the groove 60 on the array substrate 20.

By disposing the sinker 231 at the position corresponding to the groove 60 on the planarization layer and forming the retaining wall 40, the portion of the retaining wall 40 at the sinker 231 will form a stepped structure such that a small amount of ink droplets spilling over the retaining wall 40 will preferentially flow into the groove 60, which is lower.

### Embodiment Three

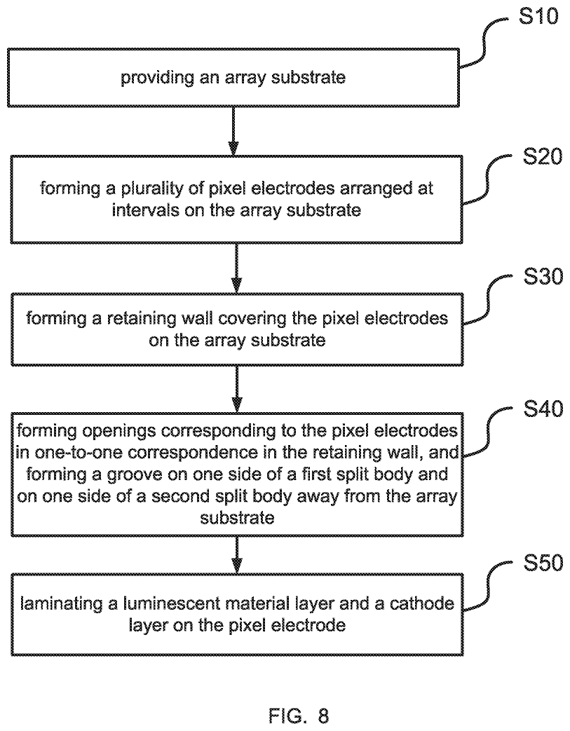

Based on the above OLED display panel, the present invention further provides a manufacturing method of an OLED display panel, as shown in FIG. 8, including steps of:

S10, providing an array substrate 20;

Step S20, forming a plurality of pixel electrodes 30 arranged at intervals on the array substrate 20;

Step S30, forming a retaining wall 40 covering the pixel electrodes 30 on the array substrate 20;

Step S40, forming openings 50 corresponding to the pixel electrodes 30 in one-to-one correspondence in the retaining wall 40, and forming a groove 60 on one side of a first split body 41 and on one side of a second split body 42 away from the array substrate 20; and Step S50, laminating a luminescent material layer 70 and a cathode layer 80 on the pixel electrode 30.

Specifically, after forming the pixel electrodes 30 on the array substrate 20 and forming the retaining wall 40 covering the pixel electrodes 30 with the hydrophilic organic material, the openings 50 corresponding to the pixel electrodes 30 are formed in the retaining wall 40 using a half mask process while forming the grooves 60.

In one embodiment, after forming the grooves 60, the top and sides of the retaining wall 40 are selectively converted from hydrophilic to hydrophobic using a mask and ultraviolet light illumination, while the bottom and sides of the groove 60 remains to be hydrophilic.

Specifically, in actual implementation, after forming the retaining wall 40 by using other materials, it is also possible to form a hydrophobic layer on the top and sides of the retaining wall 40 using a hydrophobic material, and to form the hydrophilic hydrophilic layer 90 on the side walls and the bottom of the groove 60 using a hydrophilic material having hydrophilicity.

The benefits of the present invention are: by providing grooves 60 on the first split bodies 41 and second split bodies 42, as the luminescent material layer 70 is formed in the openings 50 by inkjet printing, the small amount of ink droplets spilling over the retaining wall 40 can smoothly enter the grooves 60 for storage and then, the ink droplets evaporate during subsequent evaporation process of solvent. Thus, the ink droplets are prevented from crossing the retaining wall 40 and entering adjacent pixel openings 50 to result in mixing of different ink drop materials and to reduce the risk of color mixing as forming the luminescent material layer 70 by using ink jet printing.

In summary, although the above preferred embodiments of the present invention are disclosed, the foregoing preferred embodiments are not intended to limit the invention, those skilled in the art can make various kinds of alterations and modifications without departing from the spirit and scope of the present invention. Thus, the scope of protection of the present invention is defined by the scope of the claims.

What is claimed is:

1. An organic light emitting diode (OLED) display panel, wherein the OLED display panel includes:
an array substrate;
a plurality of pixel electrodes disposed at intervals on the array substrate;
a retaining wall disposed on the array substrate; and
a luminescent material layer and a cathode layer laminated on the pixel electrode;
wherein the retaining wall includes openings corresponding to the pixel electrodes in one-to-one correspondence, and the retaining wall includes a plurality of first split bodies and a plurality of second split bodies which are criss-crossed, and a groove is disposed on one side of the first split body and on one side of the second split body away from the array substrate; a longitudinal section of the groove is an inverted trapezoid; a hydrophilic layer having hydrophilicity is disposed on side walls and a bottom of the groove.

2. The OLED display panel according to claim 1, wherein the groove on the first split body along a length direction of the first split body, and the groove on the second split body along a length direction of the second split body.

3. The OLED display panel according to claim 1, wherein the grooves on all of the first split bodies and the grooves on all of the second split bodies are communicated to each other.

4. The OLED display panel according to claim 1, wherein the grooves are disposed at junctions of the first split bodies and the second split bodies.

5. The OLED display panel according to claim 4, wherein the grooves are disposed at all of the junctions of the first split bodies and the second split bodies.

6. The OLED display panel according to claim 5, wherein a sinker is disposed at a position corresponding to the groove on the array substrate, and an orthographic projection of the sinker on the array substrate encloses an orthographic projection of the groove on the array substrate.

7. The OLED display panel according to claim 1, wherein a cross section of the opening is elliptical or rounded rectangular.

8. An organic light emitting diode (OLED) display panel, wherein the OLED display panel includes:
an array substrate;
a plurality of pixel electrodes disposed at intervals on the array substrate;
a retaining wall disposed on the array substrate; and
a luminescent material layer and a cathode layer laminated on the pixel electrode;
wherein the retaining wall includes openings corresponding to the pixel electrodes in one-to-one correspondence, and the retaining wall includes a plurality of first split bodies and a plurality of second split bodies which are criss-crossed, and a groove is disposed on one side of the first split body and on one side of the second split body away from the array substrate.

9. The OLED display panel according to claim 8, wherein the groove on the first split body along a length direction of the first split body, and the groove on the second split body along a length direction of the second split body.

10. The OLED display panel according to claim 8, wherein the grooves on all of the first split bodies and the grooves on all of the second split bodies are communicated to each other.

11. The OLED display panel according to claim 8, wherein the grooves are disposed at junctions of the first split bodies and the second split bodies.

12. The OLED display panel according to claim 11, wherein the grooves are disposed at all of the junctions of the first split bodies and the second split bodies.

13. The OLED display panel according to claim 12, wherein a sinker is disposed at a position corresponding to the groove on the array substrate, and an orthographic projection of the sinker on the array substrate encloses an orthographic projection of the groove on the array substrate.

14. The OLED display panel according to claim 8, wherein a longitudinal section of the groove is an inverted trapezoid.

15. The OLED display panel according to claim 8, wherein a hydrophilic layer having hydrophilicity is disposed on side walls and a bottom of the groove.

16. The OLED display panel according to claim 8, wherein a cross section of the opening is elliptical or rounded rectangular.

17. A manufacturing method of an organic light emitting diode (OLED) display panel, including steps of:
Step S10, providing an array substrate;
Step S20, forming a plurality of pixel electrodes arranged at intervals on the array substrate;
Step S30, forming a retaining wall covering the pixel electrodes on the array substrate;
Step S40, forming openings corresponding to the pixel electrodes in one-to-one correspondence in the retaining wall, and forming a groove on one side of a first split body and on one side of a second split body away from the array substrate; and
Step S50, laminating a luminescent material layer and a cathode layer on the pixel electrode.
